(19) United States
(12) Patent Application Publication
(10) Pub. No.: US 2014/0084334 A1
(43) Pub. Date: Mar. 27, 2014

(54) POWER SEMICONDUCTOR DEVICE

(71) Applicant: KABUSHIKI KAISHA TOSHIBA, Minato-ku (JP)

(72) Inventors: Kazutoshi Nakamura, Hyogo-ken (JP); Tadashi Matsuda, Ishikawa-ken (JP); Hideaki Ninomiya, Hyogo-ken (JP)

(73) Assignee: KABUSHIKI KAISHA TOSHIBA, Minato-ku (JP)

(21) Appl. No.: 14/018,024

(22) Filed: Sep. 4, 2013

(30) Foreign Application Priority Data
Sep. 21, 2012 (JP) 2012-208979

(51) Int. Cl. H01L 29/739

(52) U.S. Cl. CPC H01L 29/7393
USPC 257/139

(57) ABSTRACT

According to one embodiment, a power semiconductor device includes first and second electrodes, first, second, third, and fourth semiconductor layers, a first control electrode, and a first insulating film. The first semiconductor layer is provided on the first electrode. The second semiconductor layer is provided on the first semiconductor layer. The third semiconductor layer is provided on the first semiconductor layer to be separated from the second semiconductor layer. The fourth semiconductor layer is provided on the third semiconductor layer. The second electrode is provided on the fourth semiconductor layer. The first control electrode is provided between the second and third semiconductor layers to be shifted toward the third semiconductor layer. The first insulating film is provided between the first semiconductor layer and the first control electrode, between the second semiconductor layer and the first control electrode, and between the third semiconductor layer and the first control electrode.

### CROSS-REFERENCE TO RELATED APPLICATIONS

This application is based upon and claims the benefit of priority from Japanese Patent Application No. 2012-208979, filed on Sep. 21, 2012; the entire contents of which are incorporated herein by reference.

### FIELD

Embodiments described herein relate generally to a power semiconductor device.

### BACKGROUND

Power semiconductor devices include IGBTs (Insulated Gate Bipolar Transistors), etc. Methods to reduce the on-voltage of the IGBT include a method in which the IE effect (carrier injection enhancement effect) is utilized. If the IE effect is utilized, a low on-voltage can be realized by increasing the discharge resistance of the holes to increase the carrier concentration on the emitter electrode side. The IE effect can be caused to occur by, for example, providing a p-type floating layer between an n-type base layer and the emitter electrode and relatively reducing the surface area of the p-type base region. However, the switching characteristics degrade in the case where the floating layer is provided. For example, the gate voltage oscillates at turn-off. Switching noise occurs easily at turn-on. Thus, there is a trade-off relationship between the decrease of the on-voltage and the improvement of the switching characteristics.

### BRIEF DESCRIPTION OF THE DRAWINGS

FIG. 1 is a schematic cross-sectional view illustrating a power semiconductor device according to a first embodiment;

FIG. 2A and FIG. 2B are schematic views illustrating the power semiconductor device according to the first embodiment;

FIG. 3 is an equivalent circuit diagram illustrating the power semiconductor device according to the first embodiment;

FIG. 4A to FIG. 4C are graphs illustrating characteristics of power semiconductor devices;

FIG. 5A to FIG. 5D, FIG. 6A to FIG. 6D, and FIG. 7A to FIG. 7C are schematic cross-sectional views in order of the processes, illustrating processes of a method for manufacturing the power semiconductor device according to the first embodiment;

FIG. 8 is a schematic cross-sectional view illustrating another power semiconductor device according to the first embodiment;

FIG. 9A to FIG. 9D are schematic cross-sectional views in order of the processes, illustrating processes of the method for manufacturing another power semiconductor device according to the first embodiment;

FIG. 10 is a schematic cross-sectional view illustrating another power semiconductor device according to the first embodiment;

FIG. 11 is a schematic cross-sectional view illustrating another power semiconductor device according to the first embodiment;

FIG. 12A to FIG. 12C are schematic cross-sectional views illustrating a power semiconductor device according to a second embodiment;

FIG. 13 is a schematic cross-sectional view illustrating another power semiconductor device according to the second embodiment; and

FIG. 14 is a schematic cross-sectional view illustrating another power semiconductor device according to the second embodiment.

### DETAILED DESCRIPTION

According to one embodiment, a power semiconductor device includes a first electrode, a first semiconductor layer, a second semiconductor layer, a third semiconductor layer, a fourth semiconductor layer, a second electrode, a first control electrode, and a first insulating film. The first semiconductor layer is provided on the first electrode and of a first conductivity type. The second semiconductor layer is provided on the first semiconductor layer and of a second conductivity type. The third semiconductor layer is provided on the first semiconductor layer to be separated from the second semiconductor layer and of the second conductivity type. The fourth semiconductor layer is provided on the third semiconductor layer and of the first conductivity type. The second electrode is provided on the fourth semiconductor layer to be electrically connected to the fourth semiconductor layer. The first control electrode is provided between the second semiconductor layer and the third semiconductor layer to be shifted toward the third semiconductor layer. The first insulating film is provided between the first semiconductor layer and the first control electrode, between the second semiconductor layer and the first control electrode, and between the third semiconductor layer and the first control electrode.

Various embodiments will be described hereinafter with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing therein above are marked with like reference numerals, and a detailed description is omitted as appropriate.

### First Embodiment

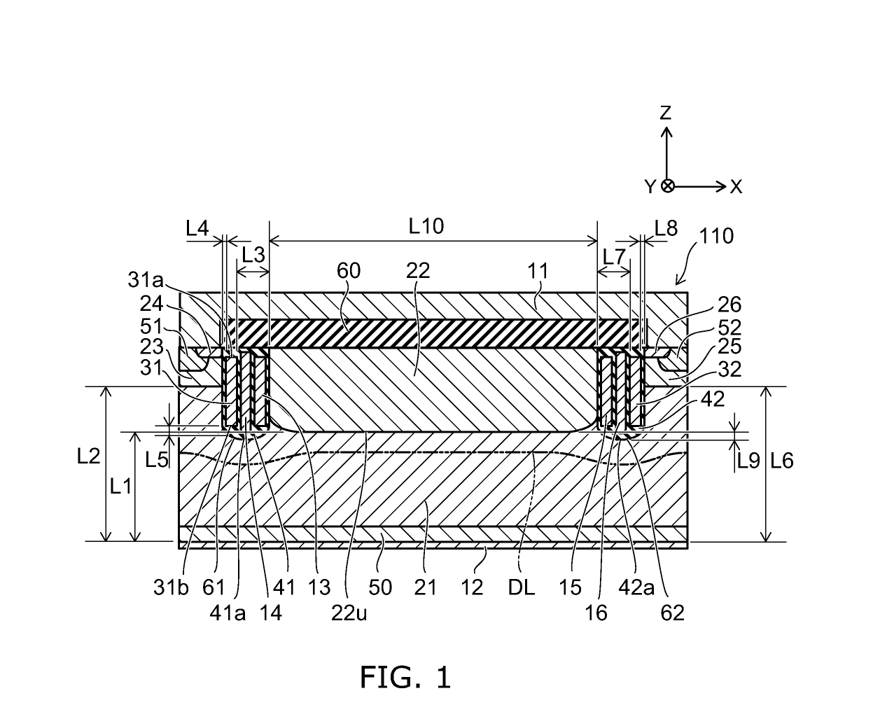

FIG. 1 is a schematic cross-sectional view illustrating a power semiconductor device according to a first embodiment.

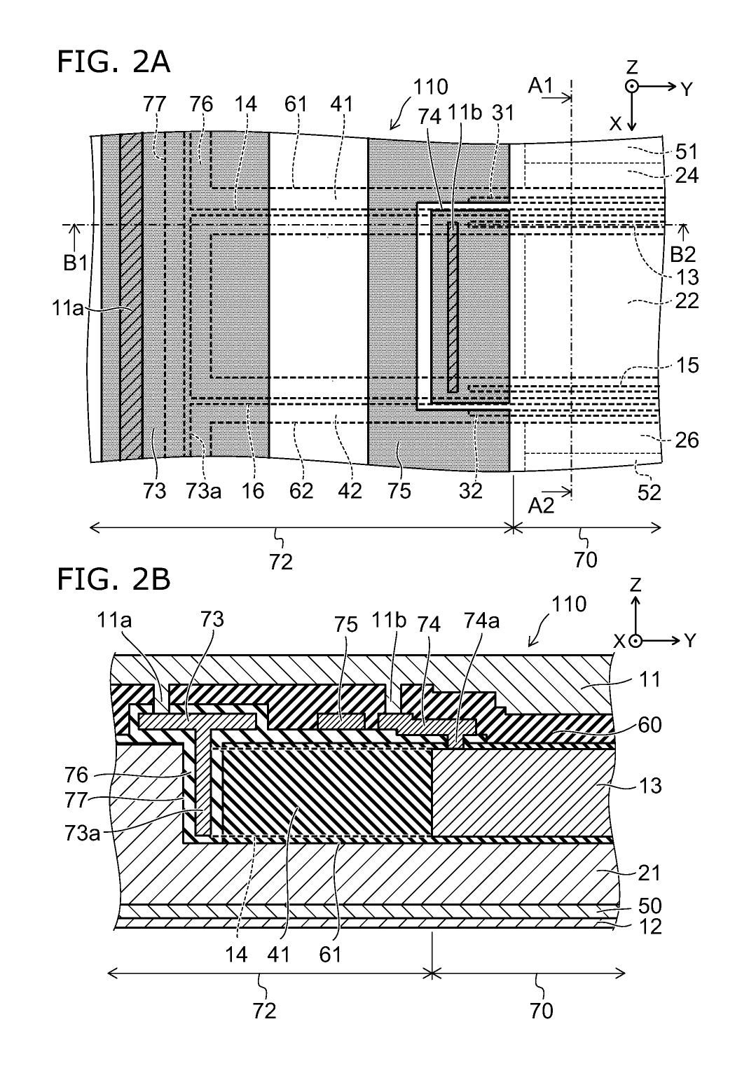

FIG. 2A and FIG. 2B are schematic views illustrating the power semiconductor device according to the first embodiment.

FIG. 2A is a schematic plan view. FIG. 2B is a schematic cross-sectional view. FIG. 1 shows a cross section along line A1-A2 of FIG. 2A. FIG. 2B shows a cross section along line B1-B2 of FIG. 2A.

As shown in FIG. 1, the IGBT 110 (the power semiconductor device) includes an emitter electrode 11 (a second electrode), a collector electrode 12 (a first electrode), an n⁻-base layer 21 (a first semiconductor layer), a floating layer 22 (a second semiconductor layer), a p-base layer 23 (a third semiconductor layer), an n⁺-emitter layer 24 (a fourth semiconductor layer), a gate electrode 31 (a first control electrode), and a gate insulating film 41 (a first insulating film). The IGBT 110 has, for example, a trench-gate structure.

The n⁻-base layer 21 is provided between the emitter electrode 11 and the collector electrode 12. In other words, the n⁻-base layer 21 is provided on the collector electrode 12; and the emitter electrode 11 is provided on the n⁻-base layer 21. The n⁻-base layer 21 is the n-type (the first conductivity type). The first conductivity type may be the p-type. In such a case, the second conductivity type is the n-type.

Herein, the stacking direction of the emitter electrode 11, the collector electrode 12, and the n⁻-base layer 21 is taken as a Z-axis direction. One direction (a first direction) perpendicular to the Z-axis direction is taken as an X-axis direction. A direction perpendicular to the Z-axis direction and the X-axis direction is taken as a Y-axis direction.

The floating layer 22 is the p-type and is provided between the emitter electrode 11 and the n⁻-base layer 21. The floating layer 22 is provided on the n⁻-base layer 21. The floating layer 22 extends along the Y-axis direction. The floating layer 22 is in an electrically floating state. In other words, the floating layer 22 is not electrically connected to the emitter electrode 11, the collector electrode 12, and the gate electrode 31.

The p-base layer 23 is the p-type and is provided between the emitter electrode 11 and the n⁻-base layer 21 to be separated from the floating layer 22 in the X-axis direction. The p-base layer 23 is provided on the n⁻-base layer 21 to be separated from the floating layer 22. The p-base layer 23 extends along the Y-axis direction. A distance L1 along the Z-axis direction between the floating layer 22 and the collector electrode 12 is shorter than a distance L2 along the Z-axis direction between the p-base layer 23 and the collector electrode 12. In other words, the diffusion depth of the floating layer 22 is deeper than the diffusion depth of the p-base layer 23. The distances L2 to L1 are, for example, not less than 0.5 μm and not more than 5 μm.

The n⁺-emitter layer 24 is the n-type and is provided between the emitter electrode 11 and the p-base layer 23. The n⁺-emitter layer 24 is provided on the p-base layer 23. The n⁺-emitter layer 24 extends along the Y-axis direction. The concentration of the impurity of the n⁺-emitter layer 24 is higher than the concentration of the impurity of the n⁻-base layer 21. The n⁺-emitter layer 24 is electrically connected to the emitter electrode 11. The n⁺-emitter layer 24 is electrically connected to the emitter electrode 11 by, for example, being in contact with the emitter electrode 11. In the specification of the application, being “electrically connected” includes not only being connected in direct contact but also includes being connected via another conductive member, etc.

The emitter electrode 11 may include, for example, aluminum. The collector electrode 12 may include, for example, a metal material such as V, Ni, Au, Ag, Sn, etc. The n⁻-base layer 21, the floating layer 22, the p-base layer 23, and the n⁺-emitter layer 24 may include, for example, a semiconductor such as silicon, etc., a compound semiconductor such as silicon carbide (SiC), gallium nitride (GaN), etc., a wide bandgap semiconductor such as diamond, etc.

The gate electrode 31 is provided between the floating layer 22 and the p-base layer 23 in the X-axis direction. The gate electrode 31 extends along the Z-axis direction and the Y-axis direction. An upper end 31a of the gate electrode 31 is positioned higher than the p-base layer 23. A lower end 31b of the gate electrode 31 is positioned lower than the p-base layer 23. In other words, the gate electrode 31 opposes in the X-axis direction the entire Z-axis direction length of the p-base layer 23. A distance L3 along the X-axis direction between the floating layer 22 and the gate electrode 31 is longer than a distance L4 along the X-axis direction between the p-base layer 23 and the gate electrode 31. In other words, the gate electrode 31 is provided to be shifted toward the p-base layer 23. The gate electrode 31 may include, for example, polysilicon.

The gate insulating film 41 is provided between the n⁻-base layer 21 and the gate electrode 31, between the floating layer 22 and the gate electrode 31, between the p-base layer 23 and the gate electrode 31, and between the n⁺-emitter layer 24 and the gate electrode 31. The gate insulating film 41 electrically insulates the n⁻-base layer 21 from the gate electrode 31, electrically insulates the floating layer 22 from the gate electrode 31, electrically insulates the p-base layer 23 from the gate electrode 31, and electrically insulates the n⁺-emitter layer 24 from the gate electrode 31. The gate insulating film 41 may include, for example, a silicon oxide film, a silicon nitride film, a silicon oxynitride film, etc.

A distance L5 along the Z-axis direction between the n⁻-base layer 21 and the lower end 31b of the gate electrode 31 is longer than the distance L4. In other words, the thickness of the gate insulating film 41 along the Z-axis direction between the n⁻-base layer 21 and the lower end 31b of the gate electrode 31 is thicker than the thickness of the gate insulating film 41 along the X-axis direction between the gate electrode 31 and the p-base layer 23. Thereby, for example, a parasitic capacitance Cgc occurring between the gate and the collector can be small. The distance along the Z-axis direction between the n⁻-base layer 21 and the lower end 31b of the gate electrode 31 changes in the X-axis direction. For example, the distance L5 is taken to be the average distance along the Z-axis direction between the n⁻-base layer 21 and the lower end 31b of the gate electrode 31.

The distance L3 is, for example, not less than 0.6 μm and not more than 2.0 μm. The distance L4 is, for example, not less than 50 nm and not more than 300 nm. The distance L5 is, for example, not less than 0.5 μm and not more than 4 μm. A distance L9 along the Z-axis direction between a lower end 22u of the floating layer 22 and a lower end 41a of the gate insulating film 41 is, for example, not less than 0.1 μm and not more than 1 μm.

The IGBT 110 further includes a p⁺-collector layer 50 (an intermediate layer), a p⁺-contact layer 51, an insulating film 60, and a trench 61.

The p⁺-collector layer 50 is the p-type and is provided between the collector electrode 12 and the n⁻-base layer 21. The p⁺-collector layer 50 is electrically connected to the collector electrode 12 and the n⁻-base layer 21.

The p⁺-contact layer 51 is the p-type and is provided between the emitter electrode 11 and the p-base layer 23. The p⁺-contact layer 51 extends along the Y-axis direction. The concentration of the impurity of the p⁺-contact layer 51 is higher than the concentration of the impurity of the p-base layer 23. The p⁺-contact layer 51 is electrically connected to the emitter electrode 11 and the p base layer 23. Thereby, the p-base layer 23 is electrically connected to the emitter electrode 11 via the p⁺-contact layer 51. Thereby, for example, the holes stored in the p-base layer 23 become easy to discharge to the emitter electrode 11.

The insulating film 60 is provided between the emitter electrode 11 and the floating layer 22 to electrically insulate the emitter electrode 11 from the floating layer 22.

The trench 61 is provided between the floating layer 22 and the p-base layer 23 in the X-axis direction. The trench 61 extends along the Z-axis direction and the Y-axis direction. The gate electrode 31 and the gate insulating film 41 are provided in the interior of the trench 61.

The n⁺-emitter layer 24 is provided between the gate insulating film 41 and the p⁺-contact layer 51 in the X-axis direction. The n⁺-emitter layer 24 is disposed to be proximal to the gate insulating film 41 (the trench 61). For example, the n⁺-emitter layer 24 contacts the gate insulating film 41 in the X-axis direction.

The IGBT 110 further includes an electrode 13 (a third electrode) and an electrode 14 (a fourth electrode).

The electrode 13 and the electrode 14 are provided in the interior of the trench 61. In other words, the three electrodes of the gate electrode 31, the electrode 13, and the electrode 14 are provided in the interior of the trench 61.

The electrode 13 is provided between the floating layer 22 and the gate electrode 31 in the X-axis direction to extend along the Z-axis direction and the Y-axis direction. The electrode 13 is electrically connected to the emitter electrode 11. The length of the electrode 13 along the Z-axis direction is substantially the same as the length of the gate electrode 31 along the Z-axis direction.

The electrode 14 is provided between the gate electrode 31 and the electrode 13 in the X-axis direction to extend along the Z-axis direction and the Y-axis direction. The electrode 14 opposes in the X-axis direction the entire Z-axis direction length of the gate electrode 31. The electrode 14 opposes in the X-axis direction the entire Z-axis direction length of the electrode 13. The electrode 14 is electrically connected to the emitter electrode 11. The electrode 13 and the electrode 14 may include, for example, polysilicon.

The gate insulating film 41 extends between the n⁻-base layer 21 and the electrode 13, between the floating layer 22 and the electrode 13, between the n⁻-base layer 21 and the electrode 14, between the gate electrode 31 and the electrode 14, and between the electrode 13 and the electrode 14.

The IGBT 110 further includes an electrode 15, an electrode 16, a p-base layer 25 (a fifth semiconductor layer), an n⁺-emitter layer 26 (a sixth semiconductor layer), a gate electrode 32 (a second control electrode), a gate insulating film 42 (a second insulating film), a p⁺-contact layer 52, and a trench 62.

The p-base layer 25 is the p-type and is provided between the emitter electrode 11 and the n⁻-base layer 21 to be separated from the floating layer 22 in the X-axis direction. The floating layer 22 is provided between the p-base layer 23 and the p-base layer 25 in the X-axis direction. In other words, the p-base layer 25 is provided on the n⁻-base layer 21 to be separated from the floating layer 22 on the side of the floating layer 22 opposite to the p-base layer 23 in the X-axis direction. The p-base layer 25 extends along the Y-axis direction. The distance L1 along the Z-axis direction between the floating layer 22 and the collector electrode 12 is shorter than a distance L6 along the Z-axis direction between the p-base layer 25 and the collector electrode 12. In other words, the diffusion depth of the floating layer 22 is deeper than the diffusion depth of the p-base layer 25. For example, the distance L6 is substantially the same as the distance L2.

The n⁺-emitter layer 26 is provided between the emitter electrode 11 and the p-base layer 25. The n⁺-emitter layer 26 is provided on the p-base layer 25. The n⁺-emitter layer 26 is electrically connected to the emitter electrode 11. The gate electrode 32 is provided between the floating layer 22 and the p-base layer 25 in the X-axis direction. A distance L7 along the X-axis direction between the floating layer 22 and the gate electrode 32 is longer than a distance L8 along the X-axis direction between the p-base layer 25 and the gate electrode 32. In other words, the gate electrode 32 is provided to be shifted toward the p-base layer 25.

The gate insulating film 42 is provided between the n⁻-base layer 21 and the gate electrode 32, between the floating layer 22 and the gate electrode 31, between the p-base layer 25 and the gate electrode 32, and between the n⁺-emitter layer 26 and the gate electrode 32. The p⁺-contact layer 52 is provided between the emitter electrode 11 and the p-base layer 25.

The trench 62 is provided between the floating layer 22 and the p-base layer 25 in the X-axis direction. The electrode 15 is provided between the floating layer 22 and the gate electrode 32 in the X-axis direction. The electrode 16 is provided between the gate electrode 32 and the electrode 15 in the X-axis direction. A distance (a width) L10 along the X-axis direction of the floating layer 22 is, for example, not less than 5 μm and not more than 50 μm. In other words, the distance L10 is the distance along the X-axis direction between the trench 61 and the trench 62.

The electrode 15, the electrode 16, the p-base layer 25, the n⁺-emitter layer 26, the gate electrode 32, the gate insulating film 42, the p⁺-contact layer 52, and the trench 62 are substantially the same as the electrode 13, the electrode 14, the p-base layer 23, the n⁺-emitter layer 24, the gate electrode 31, the gate insulating film 41, the p⁺-contact layer 51, and the trench 61, respectively. Therefore, a detailed description of the electrode 15, the electrode 16, the p-base layer 25, the n⁺-emitter layer 26, the gate electrode 32, the gate insulating film 42, the p⁺-contact layer 52, and the trench 62 is omitted.

As shown in FIG. 2A and FIG. 2B, the IGBT 110 includes a device region 70 and a terminal region 72. The device region 70 is the region where the current flows between the emitter electrode 11 and the collector electrode 12. For example, the terminal region 72 is provided around the device region 70 in the X-Y plane. The emitter electrode 11, the insulating film 60, etc., are not shown for convenience in FIG. 2A.

A first emitter interconnect 73, a second emitter interconnect 74, a gate interconnect 75, a terminal insulating film 76, and a terminal trench 77 are provided in the terminal region 72.

The first emitter interconnect 73 is provided between the n⁻-base layer 21 and the insulating film 60. The first emitter interconnect 73 may include, for example, a conductive material such as polysilicon. A plug portion 11a is provided in the emitter electrode 11 to extend along the Z-axis direction to contact the first emitter interconnect 73. Thereby, the first emitter interconnect 73 is electrically connected to the emitter electrode 11.

A plug portion 73a is provided in the first emitter interconnect 73 to extend along the Z-axis direction and the X-axis direction. The electrode 14 extends along the Y-axis direction to contact the plug portion 73a. The electrode 16 extends along the Y-axis direction to contact the plug portion 73a. Thereby, the electrode 14 and the electrode 16 are electrically connected to the emitter electrode 11 via the first emitter interconnect 73. In the example, the electrode 14 and the electrode 16 are continuous with the plug portion 73a.

The terminal insulating film 76 is provided between the n⁻-base layer 21 and the first emitter interconnect 73 to electrically insulate the n⁻-base layer 21 from the first emitter interconnect 73. The terminal insulating film 76 may include, for example, a silicon oxide film, a silicon nitride film, a silicon oxynitride film, etc.

The terminal trench 77 extends along the Z-axis direction and the X-axis direction. The trench 61 and the trench 62 contact the terminal trench 77. The plug portion 73a is provided in the interior of the terminal trench 77. A portion of the terminal insulating film 76 is provided in the interior of the terminal trench 77 to electrically insulate the n⁻ base layer 21 from the plug portion 73a.

The second emitter interconnect 74 is disposed between the n⁻-base layer 21 and the insulating film 60 to be separated from the first emitter interconnect 73. The second emitter interconnect 74 is provided on a portion of the electrode 13 and on a portion of the electrode 15.

The terminal insulating film 76 and the gate insulating film 41 are provided between the second emitter interconnect 74 and the electrode 13. The terminal insulating film 76 and the gate insulating film 42 are provided between the second emitter interconnect 74 and the electrode 15. The second emitter interconnect 74 may include, for example, a conductive material such as polysilicon, etc. A plug portion 11b is provided in the emitter electrode 11 to extend along the Z-axis direction to contact the second emitter interconnect 74. Thereby, the second emitter interconnect 74 is electrically connected to the emitter electrode 11.

A plug portion 74a is provided in the second emitter interconnect 74 to extend along the Z-axis direction to contact the electrode 13. Also, a plug portion (not shown) is provided in the second emitter interconnect 74 to extend along the Z-axis direction to contact the electrode 13. Thereby, the electrode 13 and the electrode 15 are electrically connected to the emitter electrode 11 via the second emitter interconnect 74.

The gate interconnect 75 is disposed between the n⁻-base layer 21 and the insulating film 60 to be separated from the first emitter interconnect 73 and the second emitter interconnect 74. Also, the gate interconnect 75 is provided on a portion of the gate electrode 31 and on a portion of the gate electrode 32. The terminal insulating film 76 and the gate insulating film 41 are provided between the gate interconnect 75 and the gate electrode 31. The terminal insulating film 76 and the gate insulating film 42 are provided between the gate interconnect 75 and the gate electrode 32. The gate interconnect 75 may include, for example, a conductive material such as polysilicon, etc.

A plug portion is provided in the gate interconnect 75 to extend along the Z-axis direction to contact the gate electrode 31. A plug portion is provided in the gate interconnect 75 to extend along the Z-axis direction to contact the gate electrode 32. Thereby, the gate electrode 31 and the gate electrode 32 are electrically connected to each other via the gate interconnect 75. The gate interconnect 75 is electrically connected to a not-shown metal electrode in the terminal region 72.

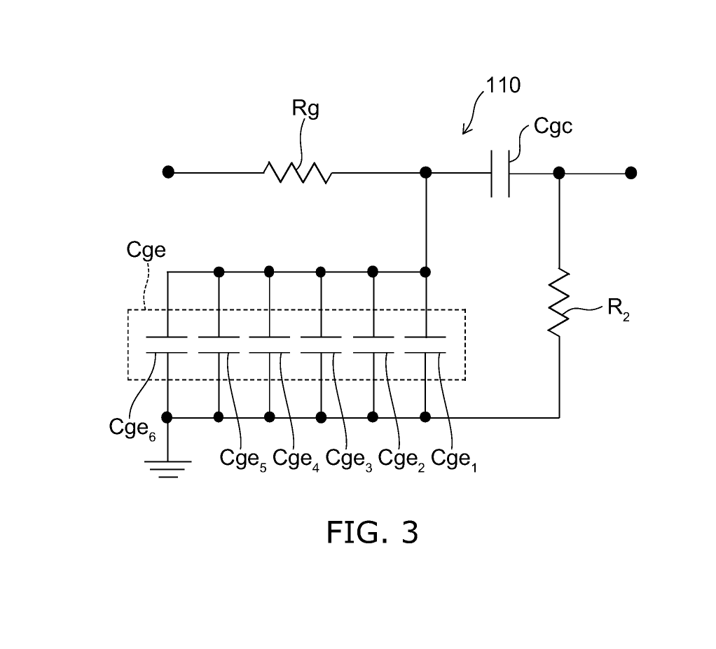

FIG. 3 is an equivalent circuit diagram illustrating the power semiconductor device according to the first embodiment.

As shown in FIG. 3, the IGBT 110 includes a gate resistance Rg electrically connected to the gate electrode 31 and the gate electrode 32, a parasitic capacitance Cge occurring between the gate and the emitter, the parasitic capacitance Cgc occurring between the gate and the collector, and an output resistance R₂ between the emitter and the collector. The capacitance Cge includes a parasitic capacitance Cge₁ occurring between the emitter electrode 11 and the gate electrode 31, a parasitic capacitance Cge₂ occurring between the emitter electrode 11 and the gate electrode 32, a parasitic capacitance Cge₃ occurring between the electrode 13 and the gate electrode 31, a parasitic capacitance Cge₄ occurring between the electrode 14 and the gate electrode 31, a parasitic capacitance Cge₅ occurring between the electrode 15 and the gate electrode 32, and a parasitic capacitance Cge₆ occurring between the electrode 16 and the gate electrode 32. The capacitance Cge is, for example, Cge₁+Cge₂+Cge₃+Cge₄+Cge₅+Cge₆.

Thus, by providing the electrodes 13 to 16, the capacitance Cge can be large. For example, the capacitance Cge can be adjusted by adjusting the surface area of the portion of the gate electrode 31 opposing the electrode 13 or by adjusting the surface area of the portion of the gate electrode 31 opposing the electrode 14.

Operations of the IGBT 110 will now be described.

For example, a positive voltage is applied to the collector electrode 12; the emitter electrode 11 is grounded; and a positive voltage is applied to the gate electrode 31 and the gate electrode 32. Thereby, a current flows between the emitter electrode 11 and the collector electrode 12. When a voltage equal to or greater than the threshold voltage is applied to the gate electrode 31 and the gate electrode 32, an inversion channel is formed in the region of the p base layer 23 proximal to the gate insulating film 41 and in the region of the p-base layer 25 proximal to the gate insulating film 42. For example, the current flows from the collector electrode 12 to the emitter electrode 11 by way of the p⁺-collector layer 50, the n⁻-base layer 21, the inversion channel, the n⁺-emitter layer 24, and the n⁺-emitter layer 26.

Effects of the IGBT 110 will now be described.

By providing the floating layer 22, the discharge resistance of the holes flowing in the emitter electrode 11 can be increased. In other words, the IE effect is obtained. Thereby, the injection efficiency of the electrons from the emitter electrode 11 is increased; and the carrier concentration on the emitter electrode 11 side is increased. Thereby, a high breakdown voltage and a low on-voltage can be realized. There are cases where the IGBT 110 utilizing the IE effect is called an IEGT (injection-Enhanced Gate Bipolar Transistor).

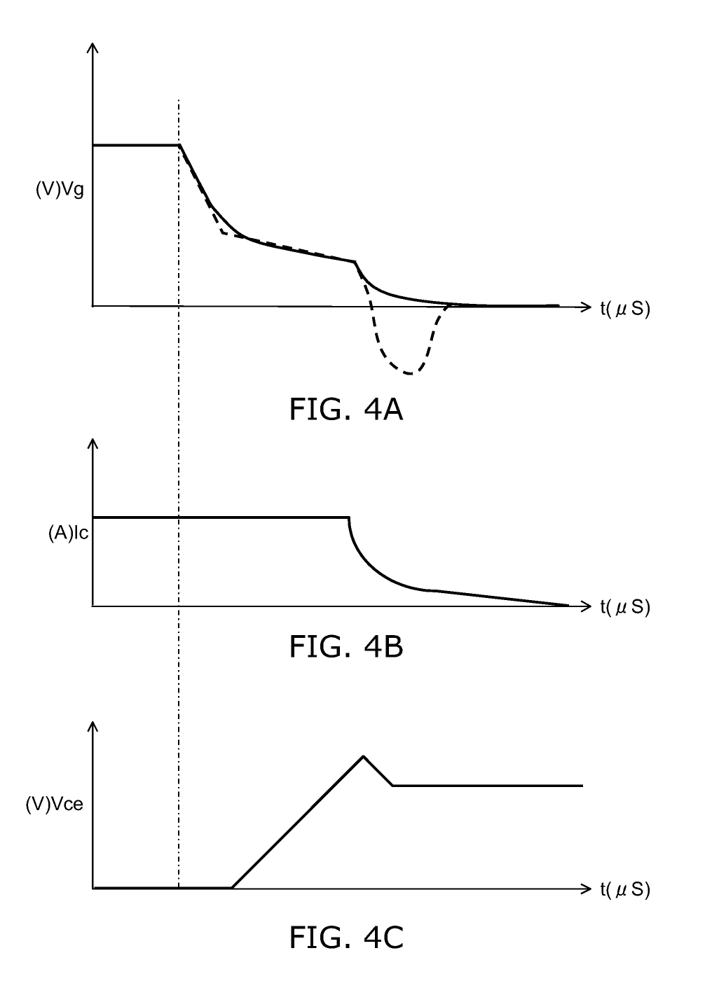

FIG. 4A to FIG. 4C are graphs illustrating characteristics of power semiconductor devices.

These drawings show the characteristics of the IGBT 110 at turn-off. In these drawings, the solid lines are the characteristics of the IGBT 110 according to the embodiment; and the broken line is the characteristic of an IGBT of a reference example.

In the reference example, only the gate electrode 31 is provided inside the trench 61; the distance L3 is substantially the same as the distance L4; only the gate electrode 32 is provided inside the trench 62; and the distance L7 is substantially the same as the distance L8.

In these drawings, the horizontal axis is the time t. The vertical axis of FIG. 4A is a gate voltage Vg; the vertical axis of FIG. 4B is a collector current Ic; and the vertical axis of FIG. 4C is a voltage Vice between the collector and the emitter.

In the IGBT of the reference example as illustrated by the broken line in FIG. 4A, for example, the gate voltage Vg swings greatly to the negative side at turn-off. In other words, in the reference example, the gate voltage Vg oscillates at turn-off. In the case where the gate voltage Vg swings to the negative side, it becomes necessary to take countermeasures for the voltage on the negative side in the circuit that drives the IGBT. Therefore, the circuit may need to be more complex. Also, the IGBT of the reference example has the problem that the temporal rate of change (dV/dt) of the voltage between the collector and the emitter at turn-on is large. Although the large dV/dt can reduce the turn-on time, the large dV/dt easily causes switching noise. Thus, the switching characteristics of the IGBT of the reference example are problematic.

The inventor of the application discovered that the oscillation of the gate voltage Vg at turn-off is caused by the holes stored in the floating layer 22. For example, the floating layer 22 stores many holes in the turned-on state. The holes stored in the floating layer 22 flow into the emitter electrode 11 via the p-base layer 23 and the p⁺-contact layer 51 as the voltage Vice increases at turn-off. At this time, the potential of the floating layer 22 abruptly changes. The potential of the floating layer 22 abruptly decreases as the holes move. A displacement current that accompanies the potential change of the floating layer 22 flows in the gate electrode 31 to cause the gate voltage Vg to oscillate.

In the IGBT 110 according to the embodiment, the distance L3 along the X-axis direction between the floating layer 22 and the gate electrode 31 is longer than the distance L4 along the X-axis direction between the p base layer 23 and the gate electrode 31. Thereby, the displacement current flowing in the gate electrode 31 is suppressed.

Thereby, as illustrated by the solid line in FIG. 4A, the oscillation of the gate voltage Vg at turn-off is suppressed. The effects of the floating layer 22 on the gate are suppressed; and the operation when switching stabilizes. In the IGBT 110, a power semiconductor device having good switching characteristics and a low on-voltage is obtained.

In the embodiment, the electrode 13 and the electrode 14 are electrically connected to the emitter electrode 11. Therefore, the electrode 13 and the electrode 14 are set to be, for example, the ground potential. The potentials of the electrode 13 and the electrode 14 are used as barriers to the holes stored in the floating layer 22. Thereby, the holes stored in the floating layer 22 that flow into the emitter electrode 11 are appropriately suppressed.

The oscillation of the gate voltage Vg occurs when the condition of Formula (1) is satisfied.

$$\begin{matrix}[ Formula 1 ] & \\ gm > \frac{1}{Rg} + \frac{1}{{R}_{2}} ( 1 + \frac{Cge}{Cgc} ) & ( 1 )\end{matrix}$$

As shown in Formula (1), the oscillation of the gate voltage Vg correlates with a transconductance gm, the gate resistance Rg, the output resistance R₂, the capacitance Cge, and the capacitance Cgc of the IGBT 110. The oscillation of the gate voltage Vg is proportional to the magnitude of the transconductance gm. The gate voltage Vg oscillates more markedly as the transconductance gm continues to become greater than the right side of the inequality formula of Formula (1).

In the IGBT 110, the capacitance Cge can be large due to the electrodes 13 to 16. Also, the capacitance Cgc can be small by increasing the thickness of the gate insulating film 41 between the n⁻-base layer 21 and the lower end 31b of the gate electrode 31. In the IGBT 110, the right side of the inequality formula of Formula (1) can be large. Thereby, the oscillation of the gate voltage Vg is suppressed even in the case where the displacement current flows in the gate electrode 31 when the potential of the floating layer 22 changes.

Further, dV/dt can be reduced by increasing the capacitance Cge, i.e., the input capacitance. Thereby, the occurrence of the switching noise that accompanies the large dV/dt also is suppressed.

A method for manufacturing the IGBT 110 will now be described.

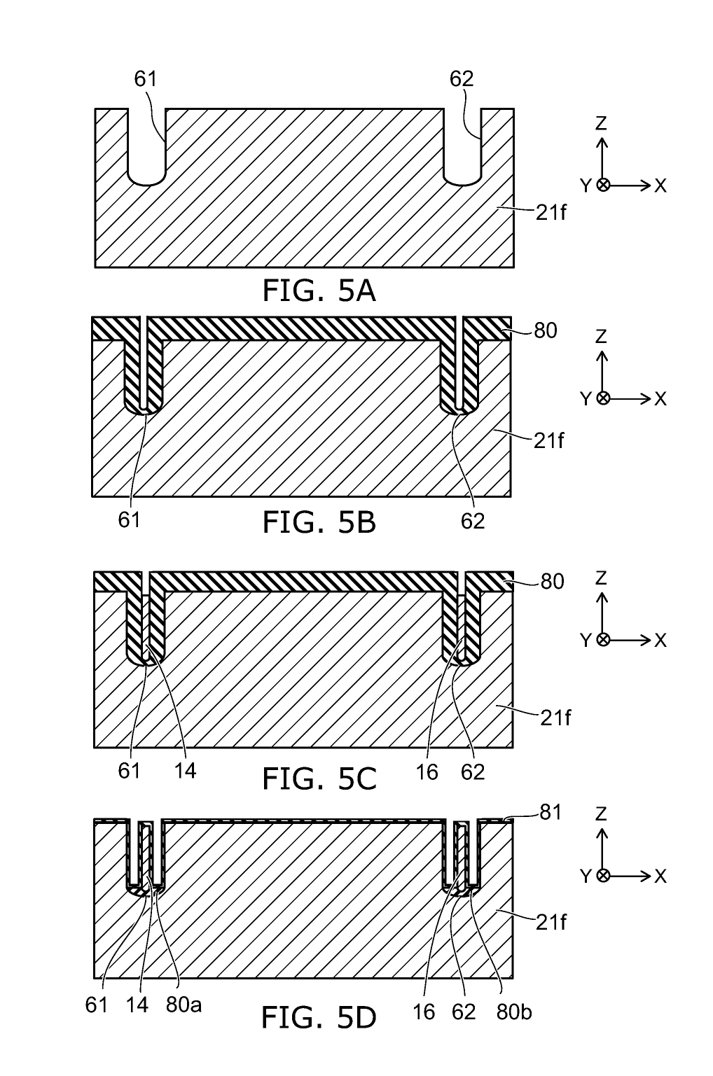

FIG. 5A to FIG. 5D, FIG. 6A to FIG. 6D, and FIG. 7A to FIG. 7C are schematic cross-sectional views in order of the processes, illustrating processes of the method for manufacturing the power semiconductor device according to the first embodiment.

As shown in FIG. 5A, the trench 61 and the trench 62 are made by photolithography and etching in an n-type semiconductor substrate 21f that is used to form the n⁻ base layer 21.

As shown in FIG. 5B, an insulating layer 80 that is used to form a portion of the gate insulating film 41 and a portion of the gate insulating film 42 is formed on the n-type semiconductor substrate 21f. A portion of the insulating layer 80 is provided along the inner wall of the trench 61. One other portion of the insulating layer 80 is provided along the inner wall of the trench 62.

As shown in FIG. 5C, the electrode 14 and the electrode 16 are formed by filling a conductive material into the space remaining inside the trench 61 and the space remaining inside the trench 62. The electrode 16 may be formed separately from the electrode 14.

As shown in FIG. 5D, the insulating layer 80 is removed by photolithography and etching to leave a portion 80a inside the trench 61 and a portion 80b inside the trench 62. An insulating layer 81 that is used to form a portion of the gate insulating film 41 and a portion of the gate insulating film 42 is formed on the n-type semiconductor substrate 21f. A portion of the insulating layer 81 is provided along the inner wall of the trench 61. Thereby, the gate insulating film 41 is formed of the portion 80a and the insulating layer 81. The gate insulating film 42 is formed of the portion 80b and the insulating layer 81. One other portion of the insulating layer 81 is provided along the inner wall of the trench 62. The thickness of the insulating layer 81 is set to be thinner than the thickness of the insulating layer 80. Thereby, the distance L5 can be longer than the distance L4.

As shown in FIG. 6A, the gate electrode 31, the gate electrode 32, the electrode 13, and the electrode 15 are formed by filling a conductive material into the spaces remaining inside the trench 61 and the spaces remaining inside the trench 62. Thereby, the distance L3 can be longer than the distance L4. The distance L7 can be longer than the distance L8. Thus, the distance L3, the distance L4, the distance L7, and the distance L8 can be appropriately set by providing the three electrodes in the interior of the trench 61 and the three electrodes in the interior of the trench 62. The gate electrode 31, the gate electrode 32, the electrode 13, and the electrode 15 may be formed individually.

As shown in FIG. 6B, the floating layer 22 is formed in at least a portion of the region of the n-type semiconductor substrate 21f between the trench 61 and the trench 62 by photolithography and ion implantation.

As shown in FIG. 6C, a p-type portion 23f that is used to form the p-base layer 23 and a p-type portion 25f that is used to form the p-base layer 25 are formed in portions of the region of the n-type semiconductor substrate 21f on the upper side by photolithography and ion implantation. The trench 61 is provided between the floating layer 22 and the p-type portion 23f in the X-axis direction. The trench 62 is provided between the floating layer 22 and the p-type portion 25f in the X-axis direction. The p-type portion 25f may be formed separately from the p-type portion 23f.

As shown in FIG. 6D, the p⁺-contact layer 51 and the p⁺-contact layer 52 are formed by photolithography and ion implantation. The p⁺-contact layer 51 is provided in a portion of the region of the p-type portion 23f on the upper side to be separated from the trench 61 in the X-axis direction. The p⁺-contact layer 52 is provided in a portion of the region of the p-type portion 25f on the upper side to be separated from the trench 62 in the X-axis direction. The p⁺-contact layer 52 may be formed separately from the p⁺-contact layer 51.

As shown in FIG. 7A, the n⁺-emitter layer 24 and the n⁺-emitter layer 26 are formed by photolithography and ion implantation. The n⁺-emitter layer 24 is provided between the p⁺-contact layer 51 and the trench 61 in the X-axis direction. The n⁺-emitter layer 26 is provided between the p⁺-contact layer 52 and the trench 62 in the X-axis direction. Thereby, the p-base layer 23 is formed from the p-type portion 23f; and the p-base layer 25 is formed from the p-type portion 25f. The n⁺-emitter layer 26 may be formed separately from the n⁺-emitter layer 24.

As shown in FIG. 7B, the p⁺-collector layer 50 is formed in the region of the n-type semiconductor substrate 21f on the lower side by, for example, ion implantation. Thereby, the n⁻-base layer 21 is formed from the n-type semiconductor substrate 21f. For example, the p⁺-collector layer 50 may be formed under the n-type semiconductor substrate 21f by epitaxial growth. The order of formation of the floating layer 22, the p-base layer 23, the n⁺-emitter layer 24, the p-base layer 25, the n⁺-emitter layer 26, the p⁺-collector layer 50, the p⁺-contact layer 51, and the p⁺-contact layer 52 is arbitrary and is interchangeable as appropriate.

The insulating film 60 is formed on the floating layer 22, the trench 61, and the trench 62 by photolithography and film formation.

As shown in FIG. 7C, the emitter electrode 11 is formed on the n⁺-emitter layer 24, the n⁺-emitter layer 26, the p⁺-contact layer 51, the p⁺-contact layer 52, and the insulating film 60 by, for example, sputtering, etc. For example, the collector electrode 12 is formed under the p⁺-collector layer 50 by sputtering, etc.

Thus, the IGBT 110 is completed.

A first modification of the first embodiment will now be described.

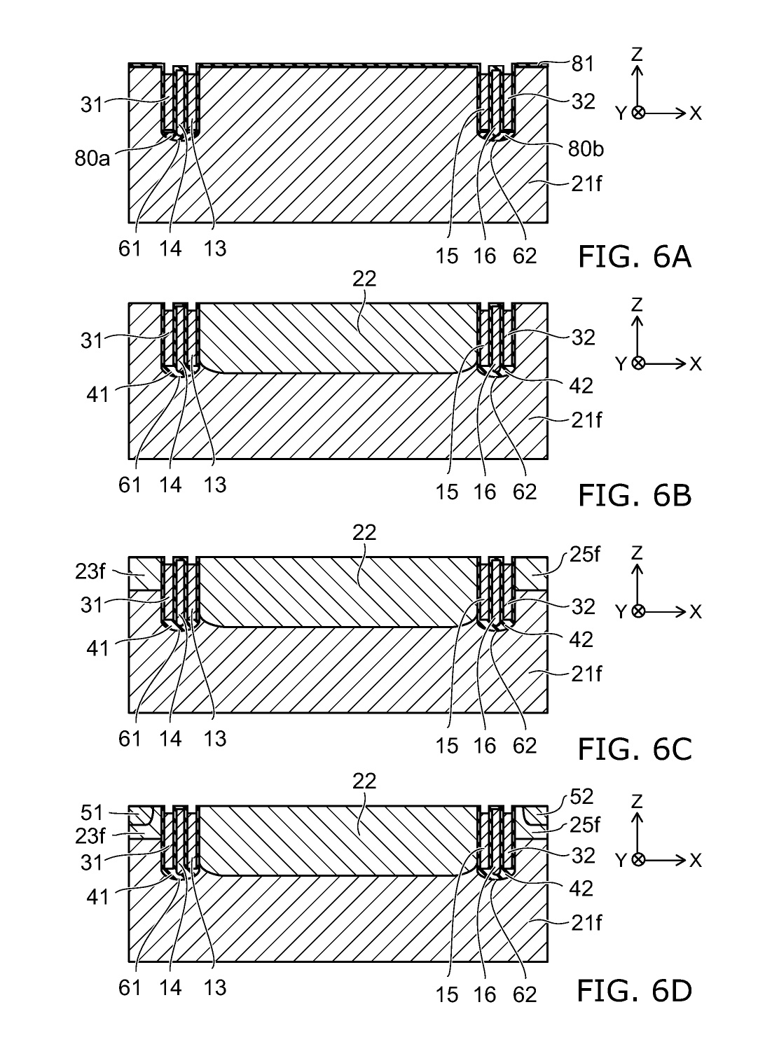

FIG. 8 is a schematic cross-sectional view illustrating another power semiconductor device according to the first embodiment.

In the IGBT 111 as shown in FIG. 8, the two electrodes of the gate electrode 31 and the electrode 13 are provided in the interior of the trench 61. The two electrodes of the gate electrode 32 and the electrode 15 are provided in the interior of the trench 62.

In the IGBT 111 as well, a power semiconductor device having good switching characteristics and a low on-voltage is obtained by setting the distance L3 to be longer than the distance L4, setting the distance L7 to be longer than the distance L8, and electrically connecting the electrode 13 and the electrode 15 to the emitter electrode 11.

A method for manufacturing the IGBT 111 will now be described.

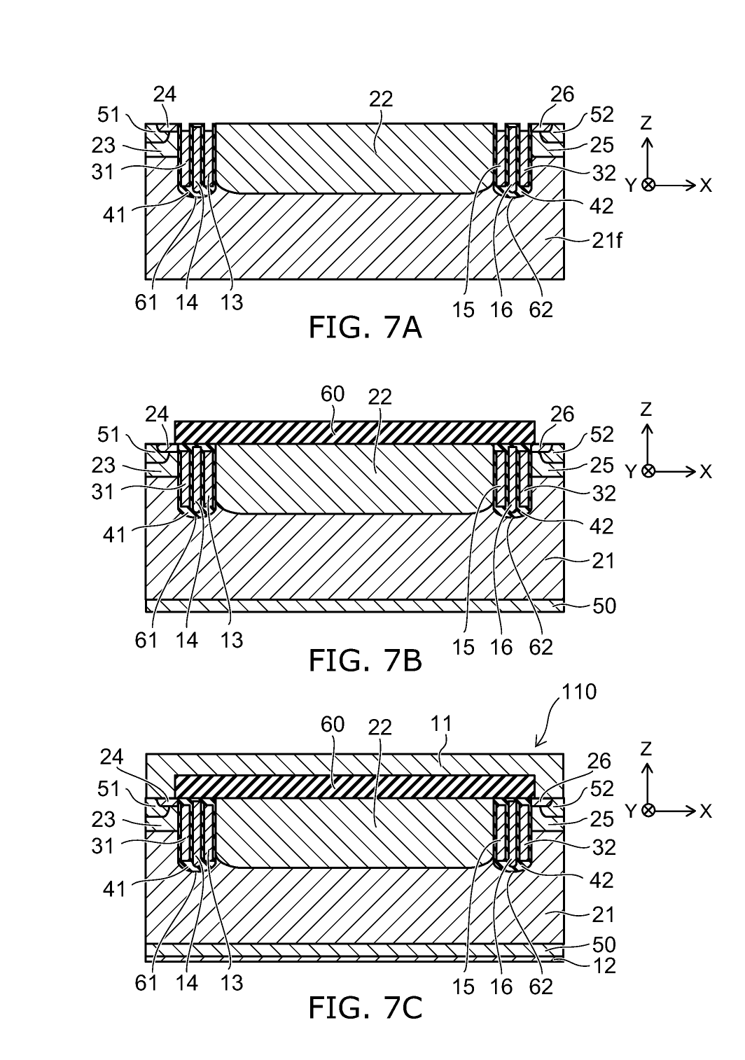

FIG. 9A to FIG. 9D are schematic cross-sectional views in order of the processes, illustrating processes of the method for manufacturing another power semiconductor device according to the first embodiment.

After making the trench 61 and the trench 62 in the n-type semiconductor substrate 21f as shown in FIG. 9A, an insulating film 83 is formed at the bottom portion inside the trench 61 and an insulating film 84 is formed at the bottom portion inside the trench 62 by film formation, photolithography, and etching. The insulating film 84 may be formed separately from the insulating film 83.

An insulating layer 85 is formed on the n-type semiconductor substrate 21f, on the insulating film 83, and on the insulating film 84 by film formation. A portion of the insulating layer 85 is provided along the inner wall of the trench 61. One other portion of the insulating layer 85 is provided along the inner wall of the trench 62. Thereby, the distance L5 can be longer than the distance L4.

As shown in FIG. 9B, a polysilicon layer 86 is formed on the insulating layer 85 by film formation. A portion of the polysilicon layer 86 is filled into the space remaining inside the trench 61. One other portion of the polysilicon layer 86 is filled into the space remaining inside the trench 62.

As shown in FIG. 9C, the gate electrode 31, the gate electrode 32, the electrode 13, and the electrode 15 are formed by removing a portion of the polysilicon layer 86 by photolithography and etching. The etching of the polysilicon layer 86 may include, for example, anisotropic etching such as RIE (Reactive Ion Etching), etc.

As shown in FIG. 9D, an insulating film 87 and an insulating film 88 are formed by filling an insulating material into the space remaining inside the trench 61 and the space remaining inside the trench 62. Thereby, the gate insulating film 41 is formed of the insulating film 83, the insulating layer 85, and the insulating film 87. The gate insulating film 42 is formed of the insulating film 84, the insulating layer 85, and the insulating film 88.

Thereafter, similarly to the IGBT 110, the formation of the floating layer 22, the formation of the p-base layer 23 and the p-base layer 25, the formation of the p⁺-contact layer 51 and the p⁺-contact layer 52, the formation of the n⁺-emitter layer 24 and the n⁺-emitter layer 26, the formation of the p⁺-collector layer 50, the formation of the insulating film 60, the formation of the emitter electrode 11, and the formation of the collector electrode 12 are performed.

Thereby, the IGBT 111 is completed.

A second modification of the first embodiment will now be described.

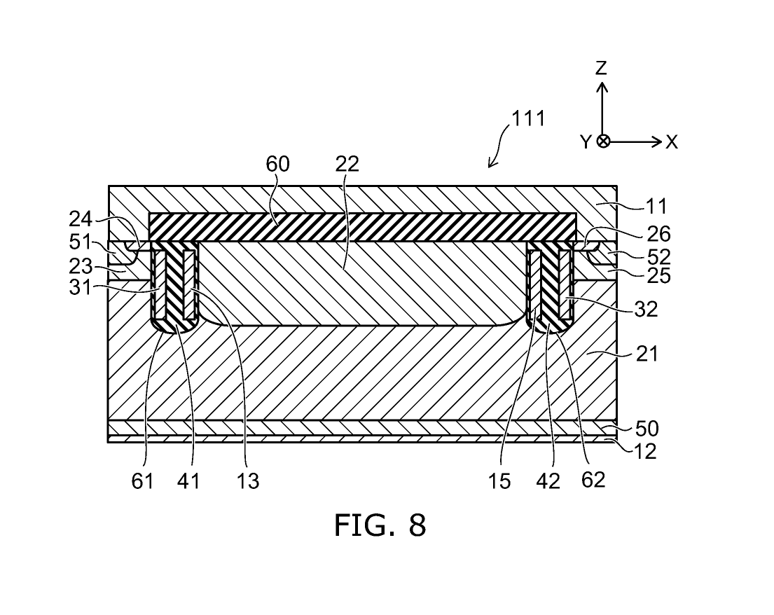

FIG. 10 is a schematic cross-sectional view illustrating another power semiconductor device according to the first embodiment.

In the IGBT 112 as shown in FIG. 10, only the gate electrode 31 is provided in the interior of the trench 61; and only the gate electrode 32 is provided in the interior of the trench 62.

In the IGBT 112 as well, a power semiconductor device having good switching characteristics and a low on-voltage is obtained by setting the distance L3 to be longer than the distance L4 and setting the distance L7 to be longer than the distance L8. The number of the electrodes provided in the interior of the trench 61 and the interior of the trench 62 may be four or more.

A third modification of the first embodiment will now be described.

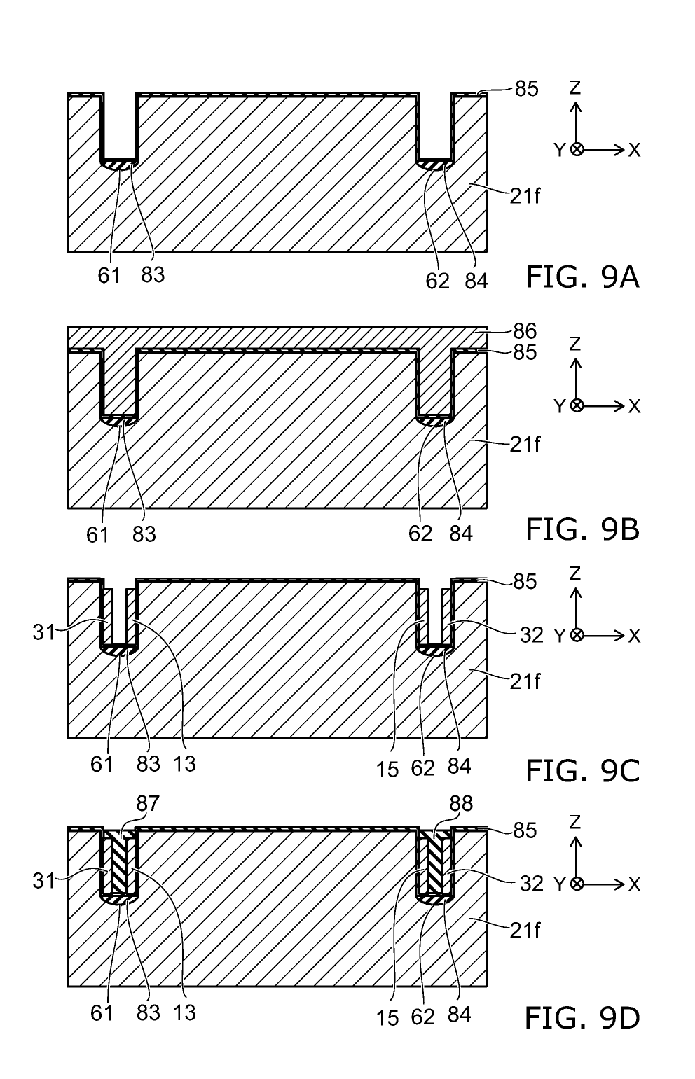

FIG. 11 is a schematic cross-sectional view illustrating another power semiconductor device according to the first embodiment.

In the IGBT 113 as shown in FIG. 11, the absolute value of the difference between the distance L1 along the Z-axis direction between the floating layer 22 and the collector electrode 12 and the distance L2 along the Z-axis direction between the p-base layer 23 and the collector electrode 12 is not more than 0.5 nm. In other words, the distance L1 along the Z-axis direction between the floating layer 22 and the collector electrode 12 is substantially the same as the distance L2 along the Z-axis direction between the p-base layer 23 and the collector electrode 12. In the IGBT 113, the distance L9 along the Z-axis direction between the lower end 22u of the floating layer 22 and the lower end 41a of the gate insulating film 41 is, for example, not less than 0.1 μm and not more than 1 μm.

In the IGBT 113 as well, similarly to the IGBT 110, a power semiconductor device having good switching characteristics and a low on-voltage is obtained. The thickness of the floating layer 22 of the IGBT 113 is thinner than the thickness of the floating layer 22 of the IGBT 110. Therefore, for example, the time of the ion implantation of the formation of the floating layer 22 can be shorter for the IGBT 113 than for the IGBT 110. The manufacturing time can be shorter for the IGBT 113 than for the IGBT 110. On the other hand, for example, the avalanche energy can be higher for the IGBT 110 than for the IGBT 113.

In the IGBT 113, a voltage is applied between the emitter electrode 11 and the collector electrode 12. Thereby, a depletion layer DL extends toward the collector electrode 12 from the pn junction portion between the n⁻-base layer 21 and the floating layer 22, from the pn junction portion between the n⁻-base layer 21 and the p-base layer 23, and from the pn junction portion between the n⁻ base layer 21 and the p-base layer 25.

In the IGBT 113, the electrodes 13 to 16 are electrically connected to the emitter electrode 11. Therefore, the portion of the depletion layer DL proximal to the electrodes 13 to 16 extends toward the collector electrode 12 more easily than the portion of the depletion layer DL around the X-axis direction central portion of the n⁻-base layer 21.

Also, in the IGBT 113, the distance L10 along the X-axis direction of the floating layer 22 is relatively long (e.g., not less than 5 μm and not more than 50 μm). Therefore, the portion of the depletion layer DL that extends from the electrode 13 side toward the electrode 15 does not easily contact the portion of the depletion layer DL that extends from the electrode 15 side toward the electrode 13. In other words, the thickness (the distance along the Z-axis direction) of the portion of the depletion layer DL proximal to the electrodes 13 to 16 is thicker than the thickness of the portion of the depletion layer DL around the X-axis direction central portion of the n⁻-base layer 21. Therefore, the electric field concentrates easily at the portion of the depletion layer DL proximal to the electrodes 13 to 16. The avalanche breakdown occurs easily at the portion of the depletion layer DL proximal to the electrodes 13 to 16.

In the IGBT 110, the distance L1 is shorter than the distance L2; and the distance L9 is, for example, not less than 0.1 μm and not more than 1 μm. Thereby, the difference between the thickness of the depletion layer DL at the portion proximal to the electrodes 13 to 16 and the thickness of the depletion layer DL at the portion around the X-axis direction central portion of the n⁻-base layer 21 can be suppressed more for the IGBT 110 than for the IGBT 113 (referring to FIG. 1). Thereby, the avalanche energy can be higher for the IGBT 110 than for the IGBT 113.

### Second Embodiment

A second embodiment will now be described.

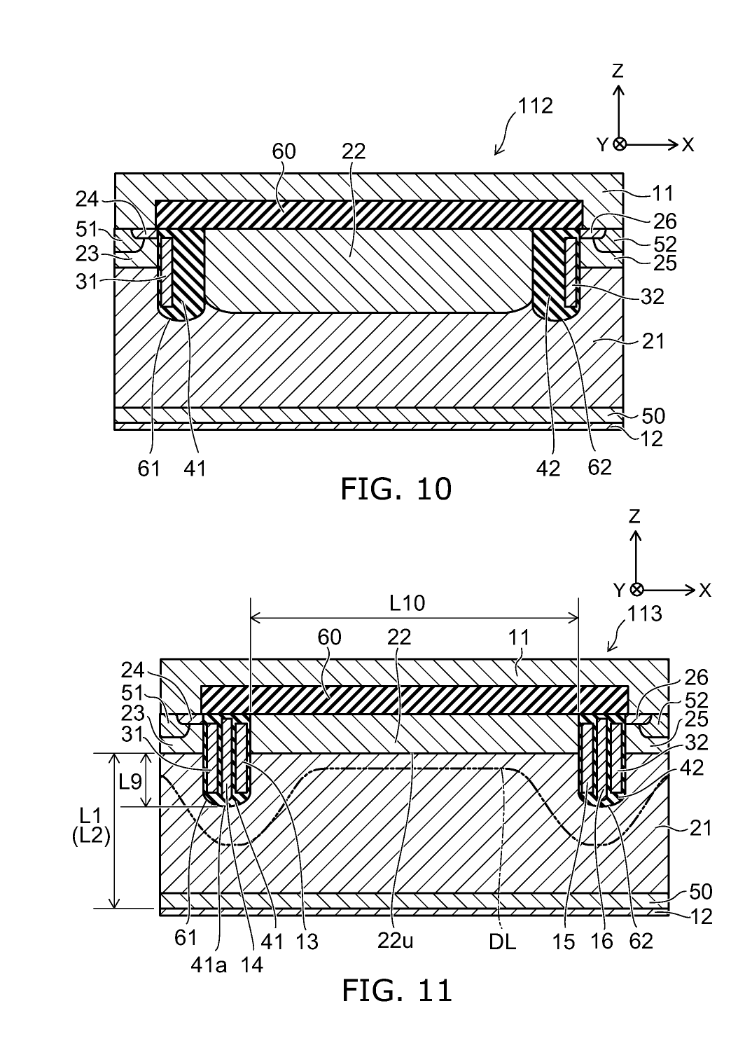

FIG. 12A to FIG. 12C are schematic cross-sectional views illustrating the power semiconductor device according to the second embodiment.

FIG. 12B and FIG. 12C are partially-enlarged views in which portions of FIG. 12A are enlarged.

As shown in FIG. 12A, the IGBT 120 further includes an electrode 91 (a first conductive unit), an electrode 92 (a second conductive unit), an electrode 93 (a third conductive unit), electrodes 94 to 96, an insulating film 43, an insulating film 44, a trench 63, and a trench 64.

The electrode 91 is provided between the gate electrode 31 and the gate electrode 32 in the X-axis direction. The electrode 91 extends along the Z-axis direction and along the Y-axis direction. The electrode 91 is electrically connected to the emitter electrode 11.

The electrode 92 is provided between the electrode 91 and the gate electrode 32 in the X-axis direction to extend along the Z-axis direction and the Y-axis direction. The electrode 92 is electrically connected to the emitter electrode 11.

The electrode 93 is provided between the electrode 91 and the electrode 92 in the X-axis direction to extend along the Z-axis direction and the Y-axis direction. The electrode 93 is electrically connected to the emitter electrode 11.

The insulating film 43 (the third insulating film) is provided between the n⁻-base layer 21 and the electrode 91, between the floating layer 22 and the electrode 91, between the n⁻-base layer 21 and the electrode 92, between the floating layer 22 and the electrode 92, between the n⁻-base layer 21 and the electrode 93, between the electrode 91 and the electrode 93, and between the electrode 92 and the electrode 93. The electrodes 91 to 93 and the insulating film 43 are provided in the interior of the trench 63.

The electrode 94 is provided between the electrode 91 and the gate electrode 32 in the X-axis direction. More specifically, the electrode 94 is provided between the electrode 92 and the gate electrode 32 in the X-axis direction. The electrode 94 extends along the Z-axis direction and the Y-axis direction. The electrode 94 is electrically connected to the emitter electrode 11.

The electrode 95 is provided between the electrode 94 and the gate electrode 32 in the X-axis direction to extend along the Z-axis direction and the Y-axis direction. The electrode 94 is electrically connected to the emitter electrode 11.

The electrode 96 is provided between the electrode 94 and the electrode 95 in the X-axis direction to extend along the Z-axis direction and the Y-axis direction. The electrode 96 is electrically connected to the emitter electrode 11.

The insulating film 44 is provided between the n⁻-base layer 21 and the electrode 94, between the floating layer 22 and the electrode 94, between the n⁻-base layer 21 and the electrode 95, between the floating layer 22 and the electrode 95, between the n⁻-base layer 21 and the electrode 96, between the electrode 94 and the electrode 96, and between the electrode 95 and the electrode 96. The electrodes 94 to 96 and the insulating film 44 are provided in the interior of the trench 64.

In the IGBT 120, the floating layer 22 has a first portion 22a, a second portion 22b, and a third portion 22c. The first portion 22a is the portion between the gate insulating film 41 and the insulating film 43 in the X-axis direction. The second portion 22b is the portion between the insulating film 43 and the gate insulating film 42 in the X-axis direction. More specifically, the second portion 22b is the portion between the insulating film 43 and the insulating film 44 in the X-axis direction. The third portion 22c is the portion between the insulating film 44 and the gate insulating film 42 in the X-axis direction. A distance L11 along the X-axis direction of the first portion 22a, a distance L12 along the X-axis direction of the second portion 22b, and a distance L13 along the X-axis direction of the third portion 22c are, for example, not less than 0.5 μm and not more than 4 μm.

In the IGBT 120, the distance L1 along the Z-axis direction between the floating layer 22 and the collector electrode 12 is substantially the same as the distance L2 along the Z-axis direction between the p-base layer 23 and the collector electrode 12; the distance L9 along the Z-axis direction between the lower end 22u of the floating layer 22 and the lower end 41a of the gate insulating film 41 is, for example, not less than 0.1 μm and not more than 1 μm; and the thickness of the floating layer 22 is, for example, not less than 0.3 μm and not more than 4 μm.

In the IGBT 120, a voltage is applied between the emitter electrode 11 and the collector electrode 12.

Directly after applying the voltage as shown in FIG. 12A, the thicknesses of the portions of the depletion layer DL proximal to the electrodes 13 to 16 and the electrodes 91 to 96 are thicker than the thickness of the portion of the depletion layer DL around the X-axis direction central portion of the first portion 22a, the thickness of the portion around the X-axis direction central portion of the second portion 22b, and the thickness of the portion around the X-axis direction central portion of the third portion 22c.

As shown in FIG. 12B, the portion of the depletion layer DL that extends from the electrode 13 side toward the electrode 91 gradually approaches the portion of the depletion layer DL that extends from the electrode 91 side toward the electrode 13. Finally, the two portions contact each other. This is because the distance L11, the distance L12, and the distance L13 are set to be shorter than, for example, the distance L10, etc., of the IGBT 113.

When the two portions contact each other as shown in FIG. 12C, the thickness of the portion of the depletion layer DL around the X-axis direction central portion of the first portion 22a becomes thicker than before the contact. The thickness of the portion of the depletion layer DL around the X-axis direction central portion of the second portion 22b becomes thicker than before the contact. The thickness of the portion of the depletion layer DL around the X-axis direction central portion of the third portion 22c becomes thicker than before the contact. Thereby, in the IGBT 120, the concentration of the electric field at the portions of the depletion layer DL proximal to the electrodes 13 to 16 and the electrodes 91 to 96 is suppressed. For example, the avalanche energy can be higher for the IGBT 120 than for the IGBT 113.

Also, the trench 63 and the trench 64 can be made simultaneously with the trench 61 and the trench 62. The electrode 93 and the electrode 96 can be formed simultaneously with the electrode 14 and the electrode 16. The electrode 91, the electrode 92, the electrode 94, and the electrode 95 can be formed simultaneously with the gate electrode 31, the gate electrode 32, the electrode 13, and the electrode 15. Therefore, in the IGBT 120, the increase of the manufacturing time of the formation of the electrodes 91 to 96, etc., is suppressed. For example, the time of the ion implantation of the formation of the floating layer 22 can be shorter for the IGBT 120 than for the IGBT 110; and the manufacturing time can be shorter.

The number of the trenches provided between the trench 61 and the trench 62 may be one, three, or more than three. For example, the number of the trenches is appropriately set according to the distance between the trench 61 and the trench 62, the avalanche energy that is necessary, etc.

A first modification of the second embodiment will now be described.

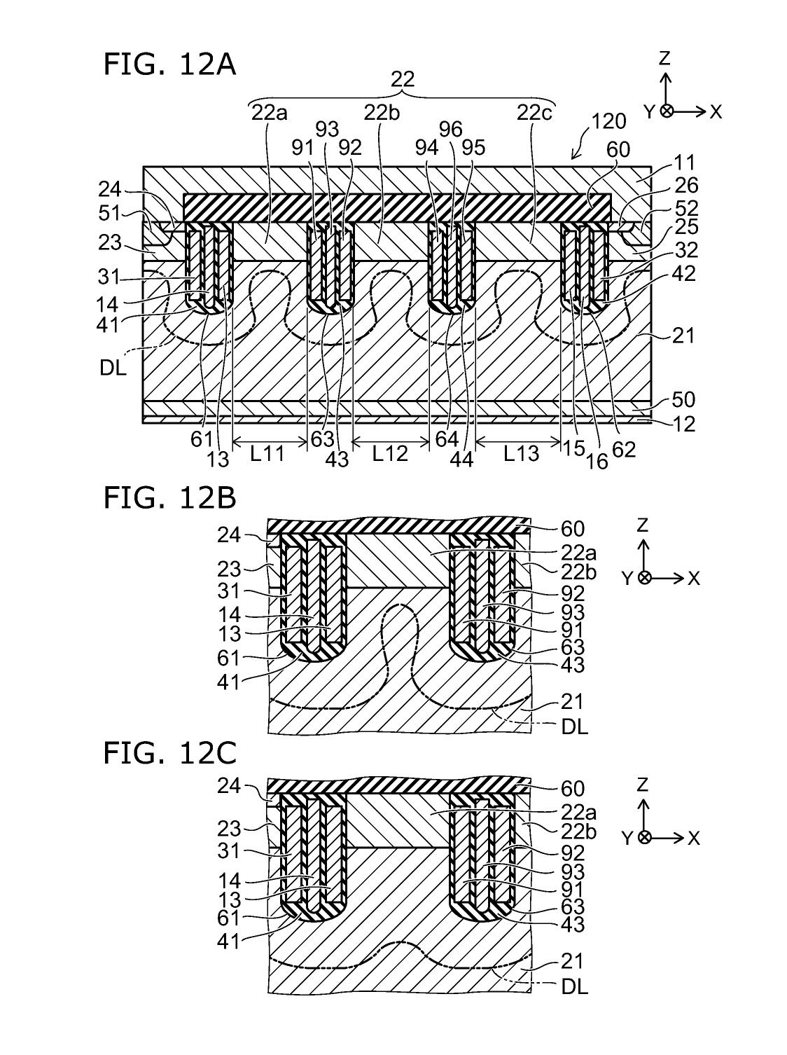

FIG. 13 is a schematic cross-sectional view illustrating another power semiconductor device according to the second embodiment.

In the IGBT 121 as shown in FIG. 13, the electrode 93 and the electrode 96 are electrically connected to the gate electrode 31 and the gate electrode 32. Thereby, the capacitance Cge can be even larger for the IGBT 121 than for the IGBT 110, the IGBT 120, etc., due to the parasitic capacitance occurring between the electrode 91 and the electrode 93, the parasitic capacitance occurring between the electrode 92 and the electrode 93, the parasitic capacitance occurring between the electrode 94 and the electrode 96, and the parasitic capacitance occurring between the electrode 95 and the electrode 96. For example, the oscillation of the gate voltage Vg at turn-off is suppressed more appropriately.

In the IGBT 121, the turn-on characteristics also can be improved. The temporal rate of change (di/dt) of the current between the collector and the emitter at turn-on is determined by the product (Rg·Cge) of the gate resistance Rg and the capacitance Cge. Although the turn-on time shortens as Rg·Cge increases, this causes switching noise. Therefore, Rg·Cge is set to a value considering the trade-off between the turn-on time and the switching noise. In the IGBT 121, Rg can be small because Cge can be large. Also, the ramp-down time of the collector voltage at turn-on is determined by the product (Rg·Cgc) of the gate resistance Rg and the capacitance Cgc. In the IGBT 121, Rg·Cgc can be small because Rg can be small. When Rg·Cgc is reduced, the ramp-down time of the collector voltage at turn-on shortens. In other words, in the IGBT 121, the ramp-down time of the collector voltage can be shortened; and the turn-on loss can be reduced.

A second modification of the second embodiment will now be described.

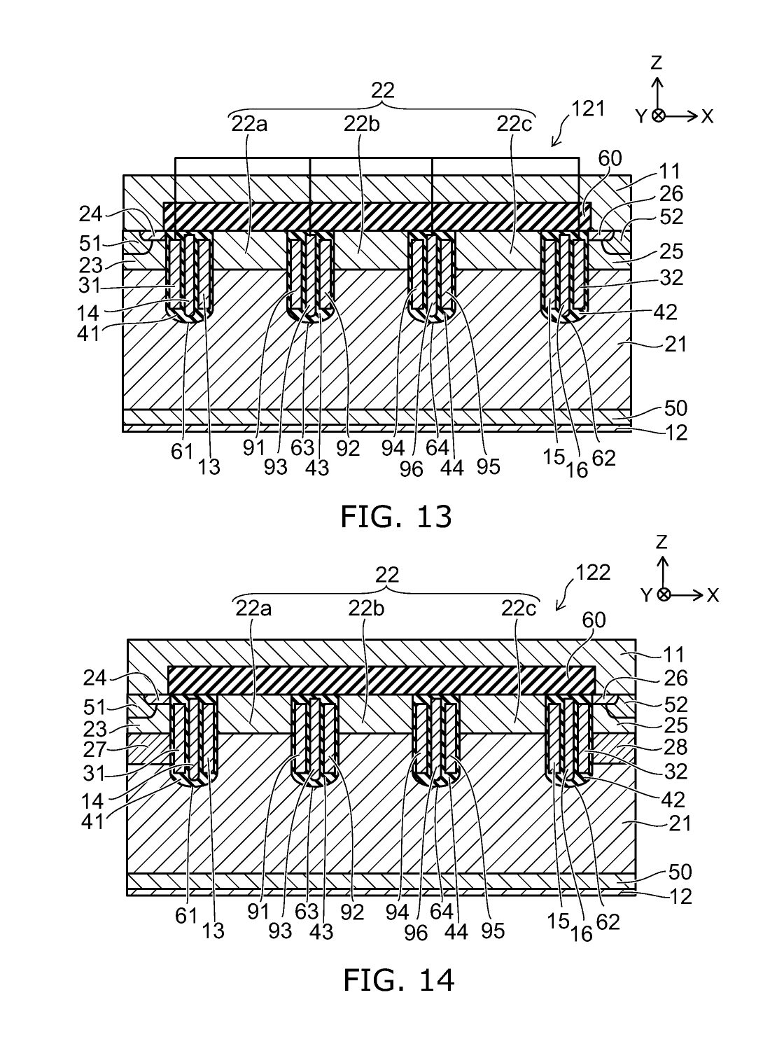

FIG. 14 is a schematic cross-sectional view illustrating another power semiconductor device according to the second embodiment.

As shown in FIG. 14, the IGBT 122 further includes an n-barrier layer 27 (a seventh semiconductor layer) and an n-barrier layer 28.

The n-barrier layer 27 is the n-type and is provided between the n⁻-base layer 21 and the p-base layer 23 in the Z-axis direction. The concentration of the impurity of the n-barrier layer 27 is higher than the concentration of the impurity of the n⁻-base layer 21. The n-barrier layer 28 is the n-type and is provided between the n⁻-base layer 21 and the p-base layer 25 in the Z-axis direction. The concentration of the impurity of the n-barrier layer 28 is higher than the concentration of the impurity of the n⁻-base layer 21.

By providing the n-barrier layer 27 and the n-barrier layer 28, the discharge resistance of the holes flowing in the emitter electrode 11 can be higher. The IE effect can be promoted more; and the on-voltage can be reduced further. The n-barrier layer 27 and the n barrier layer 28 may be provided in the IGBT 110.

An IGBT having a trench-gate structure is illustrated as the power semiconductor device in the embodiments recited above. The power semiconductor device may be, for example, a MOSFET having a trench-gate structure. In the case of the MOSFET, for example, the second electrode is used as the source electrode; the first electrode is used as the drain electrode; the fourth semiconductor layer is used as the n-source layer; and the p⁺-collector layer 50 is used as the n⁺-drain layer.

According to the embodiments, a power semiconductor device having good switching characteristics and a low on-voltage is provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the embodiments of the invention are not limited to these specific examples. For example, one skilled in the art may similarly practice the invention by appropriately selecting specific configurations of components included in the power semiconductor device such as the first to fourth electrodes, the first to seventh semiconductor layers, the first and second control electrodes, the first to third insulating films, the first to third conductive units, etc., from known art; and such practice is within the scope of the invention to the extent that similar effects are obtained.

Further, any two or more components of the specific examples may be combined within the extent of technical feasibility and are included in the scope of the invention to the extent that the purport of the invention is included.

Moreover, all power semiconductor devices practicable by an appropriate design modification by one skilled in the art based on the power semiconductor devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A power semiconductor device, comprising:
a first electrode;
a first semiconductor layer of a first conductivity type provided on the first electrode;
a second semiconductor layer of a second conductivity type provided on the first semiconductor layer;
a third semiconductor layer of the second conductivity type provided on the first semiconductor layer to be separated from the second semiconductor layer;
a fourth semiconductor layer of the first conductivity type provided on the third semiconductor layer;
a second electrode provided on the fourth semiconductor layer to be electrically connected to the fourth semiconductor layer;
a first control electrode provided between the second semiconductor layer and the third semiconductor layer to be shifted toward the third semiconductor layer; and
a first insulating film provided between the first semiconductor layer and the first control electrode, between the second semiconductor layer and the first control electrode, and between the third semiconductor layer and the first control electrode.

2. The device according to claim 1, further comprising a third electrode provided between the first control electrode and the second semiconductor layer to be electrically connected to the second electrode,
the first insulating film extending between the first semiconductor layer and the third electrode, between the second semiconductor layer and the third electrode, and between the first control electrode and the third electrode.

3. The device according to claim 2, further comprising a fourth electrode provided between the first control electrode and the third electrode to be electrically connected to the second electrode,
the first insulating film extending between the first semiconductor layer and the fourth electrode, between the first control electrode and the fourth electrode, and between the second control electrode and the fourth electrode.

4. The device according to claim 1, wherein a distance between the second semiconductor layer and the first electrode is shorter than a distance between the third semiconductor layer and the first electrode.

5. The device according to claim 1, wherein the second semiconductor layer is in an electrically floating state.

6. The device according to claim 1, further comprising:
a fifth semiconductor layer of the second conductivity type provided on the first semiconductor layer to be separated from the second semiconductor layer on a side of the second semiconductor layer opposite to the third semiconductor layer;
a sixth semiconductor layer of the first conductivity type provided on the fifth semiconductor layer to be electrically connected to the second electrode;
a second control electrode provided between the second semiconductor layer and the fifth semiconductor layer to be shifted toward the fifth semiconductor layer; and
a second insulating film provided between the first semiconductor layer and the second control electrode, between the second semiconductor layer and the second control electrode, and between the fifth semiconductor layer and the second control electrode.

7. The device according to claim 6, wherein a distance between the second semiconductor layer and the first electrode is shorter than a distance between the fifth semiconductor layer and the first electrode.

8. The device according to claim 6, further comprising:
a first conductive unit provided between the first control electrode and the second control electrode to be electrically connected to the second electrode; and
a third insulating film provided between the first semiconductor layer and the first conductive unit and between the second semiconductor layer and the first conductive unit.

9. The device according to claim 8, wherein a distance between the first insulating film and the third insulating film and a distance between the second insulating film and the third insulating film are not less than 0.5 μm and not more than 4 μm.

10. The device according to claim 8, further comprising:
a second conductive unit provided between the first conductive unit and the second control electrode; and
a third conductive unit provided between the first conductive unit and the second conductive unit,
the third insulating film extending between the first semiconductor layer and the second conductive unit, between the second semiconductor layer and the second conductive unit, between the first semiconductor layer and the third conductive unit, between the first conductive unit and the third conductive unit, and between the second conductive unit and the third conductive unit.

11. The device according to claim 10, wherein the second conductive unit and the third conductive unit are electrically connected to the second electrode.

12. The device according to claim 10, wherein
the second conductive unit is electrically connected to the second electrode, and
the third conductive unit is electrically connected to the first control electrode.

13. The device according to claim 1, further comprising a seventh semiconductor layer provided between the first semiconductor layer and the third semiconductor layer,
a concentration of an impurity of the seventh semiconductor layer being higher than a concentration of an impurity of the first semiconductor layer.

14. The device according to claim 1, wherein the first control electrode extends along a stacking direction of the first semiconductor layer, the second semiconductor layer, the third semiconductor layer, and the fourth semiconductor layer to have an upper end positioned higher than the third semiconductor layer and a lower end positioned lower than the third semiconductor layer.

15. The device according to claim 14, wherein a distance between the first semiconductor layer and the lower end of the first control electrode is longer than a distance between the first control electrode and the third electrode.

16. The device according to claim 1, wherein a concentration of an impurity of the fourth semiconductor layer is higher than a concentration of an impurity of the first semiconductor layer.

17. The device according to claim 1, further comprising an intermediate layer of the second conductivity type provided between the first electrode and the first semiconductor layer.

18. The device according to claim 1, further comprising a contact layer of the second conductivity type provided between the second electrode and the third semiconductor layer,
a concentration of an impurity of the contact layer being higher than a concentration of an impurity of the third semiconductor layer.

19. The device according to claim 1, wherein the fourth semiconductor layer contacts the first insulating film.

20. The device according to claim 1, further comprising a trench provided between the second semiconductor layer and the third semiconductor layer,
the first control electrode and the first insulating film provided in the interior of the trench,
the first control electrode provided to be shifted toward the third semiconductor layer in the trench.
